(19) United States
(12) Patent Application Publication
(10) Pub. No.: US 2026/0013310 A1
(43) Pub. Date: Jan. 8, 2026

(54) SEMICONDUCTOR STRUCTURE

(71) Applicant: Lextar Electronics Corporation, Hsinchu City (TW)

(72) Inventor: Shiou-Yi KUO, Hsinchu City (TW)

(21) Appl. No.: 19/259,574

(22) Filed: Jul. 3, 2025

(30) Foreign Application Priority Data
Jul. 3, 2024 (TW) 113124821

(51) Int. Cl. H10H 29/85; H01L 25/075; H10H 29/01; H10H 29/03; H10H 29/24; H10H 29/80; H10H 29/855

(52) U.S. Cl. CPC H10H 29/857; H01L 25/0753; H10H 29/24; H10H 29/8321; H10H 29/8421; H10H 29/8508; H10H 29/855; H10H 29/03; H10H 29/0364

(57) ABSTRACT

A semiconductor structure includes packaging structures and a substrate. Each packaging structure includes a light-transmitting layer, micro-LED chips, a first insulating layer, redistribution layers, a second insulating layer, and conductive pieces. The micro-LED chips are on the light-transmitting layer and include an electrode surface and a light-emitting surface facing the light-transmitting layer. The first insulating layer is disposed on the light-transmitting layer and surrounds the micro-LED chips. The redistribution layers are disposed on the first insulating layer and pass through the first insulating layer to be electrically connected to the electrode surfaces. The second insulating layer is disposed on the first insulating layer. The conductive pieces are disposed on the second insulating layer, pass through the second insulating layer to be electrically connected to the redistribution layers, and are between the substrate and the micro-LED chips.

### CROSS REFERENCE TO RELATED APPLICATIONS

This application claims priority of Taiwan Patent Application No. 113124821, filed on Jul. 3, 2024, the entirety of which is incorporated by reference herein.

### BACKGROUND OF THE DISCLOSURE

### Field of the Invention

The present disclosure relates to semiconductor technology, and, in particular, to a semiconductor structure with a plurality of packaging structures.

### Description of the Related Art

During the manufacturing process of semiconductor structures, a mass transfer process may be used to transfer semiconductor elements from a growth substrate to a carrier substrate, or to transfer semiconductor elements from a carrier substrate to a circuit board, so as to more easily process the semiconductor elements. However, as the sizes of these semiconductor elements are gradually scaled down, the number of semiconductor elements in a semiconductor structure increases dramatically, which poses a severe challenge to the manufacturing process. Therefore, while existing semiconductor structures and manufacturing methods thereof have gradually met their intended purposes, they do not meet requirements in all respects. There are still some issues to be overcome regarding semiconductor structures.

### BRIEF SUMMARY OF THE DISCLOSURE

In some embodiments, a semiconductor structure is provided. The semiconductor structure includes a plurality of packaging structures arranged side by side and a substrate. Each of the packaging structures includes a light-transmitting layer, a plurality of micro light-emitting diode (micro-LED) chips, a first insulating layer, a plurality of redistribution layers, a second insulating layer, and a plurality of conductive pieces. The micro light-emitting diode (micro-LED) chips are arranged side by side on the light-transmitting layer, wherein each of the micro-LED chips includes an electrode surface and a light-emitting surface opposite to the electrode surface, wherein the light-emitting surfaces of the micro-LED chips face the light-transmitting layer. The first insulating layer is disposed on the light-transmitting layer and surrounds the micro-LED chips. The redistribution layers are disposed on the first insulating layer and passing through the first insulating layer to be electrically connected to the electrode surfaces of the micro-LED chips. The second insulating layer is disposed on the first insulating layer. The conductive pieces are disposed on the second insulating layer and passing through the second insulating layer to be electrically connected to the redistribution layers. The substrate is disposed on the packaging structures, wherein the conductive pieces are between the substrate and the micro-LED chips.

The semiconductor structure of the present disclosure may be applied in a variety of electronic devices. In order to make the features and advantages of the present disclosure more comprehensible, various embodiments are specially cited hereinafter, together with the accompanying drawings, to be described in detail as follows.

### BRIEF DESCRIPTION OF THE DRAWINGS

Aspects of the present disclosure are best understood from the following detailed description when read with the accompanying figures. It should be noted that in accordance with the standard practice in the industry, various features are not drawn to scale. In fact, the dimensions of the various features may be arbitrarily increased or reduced for clarity of discussion.

FIGS. 1 to 3 are schematic cross-sectional views showing the semiconductor structure at various stages of the manufacturing method according to some embodiments of the present disclosure.

FIG. 4 is an enlarged schematic diagram showing the micro-LED chips according to some embodiments of the present disclosure.

FIGS. 5A and 5B are schematic diagrams showing the micro-LED chips in a transfer process according to some embodiments of the present disclosure.

FIGS. 6A and 6B are schematic diagrams showing the micro-LED chips in the transfer process according to other embodiments of the present disclosure.

FIGS. 7 and 8 are schematic cross-sectional views showing the semiconductor structure at various stages of the manufacturing method according to some embodiments of the present disclosure.

FIG. 9A is a schematic diagram showing the electrode and the solder paste connected together by a bonding process according to some embodiments of the present disclosure.

FIG. 9B is a schematic diagram showing the electrode and the redistribution layer connected together by an electroplating process, a sputtering process, or an electron gun evaporation process according to some embodiments of the present disclosure.

FIGS. 10 to 12A are schematic cross-sectional views showing the semiconductor structure at various stages of the manufacturing method according to some embodiments of the present disclosure.

FIG. 12B is a top view showing the packaging structure according to some embodiments of the present disclosure.

FIGS. 13 to 16A are schematic cross-sectional views showing the semiconductor structure at various stages of the manufacturing method according to some embodiments of the present disclosure.

FIGS. 16B and 16C are schematic diagrams showing the light-transmitting layer with the roughened structure of the semiconductor structure according to some embodiments of the present disclosure.

FIGS. 17 and 18 are schematic cross-sectional views showing the semiconductor structure at various stages of the manufacturing method according to some embodiments of the present disclosure.

FIGS. 19 and 20 are schematic cross-sectional views showing the semiconductor structure at various stages of the manufacturing method according to other embodiments of the present disclosure.

FIGS. 21 to 24 are schematic cross-sectional views showing the display device at various stages of the manufacturing method according to some embodiments of the present disclosure.

### DETAILED DESCRIPTION OF THE DISCLOSURE

The following disclosure provides many different embodiments or examples for implementing the provided apparatus. Specific examples of various components and their configurations are described below to simplify the embodiments of the present disclosure, but are certainly not intended to limit the present disclosure. For example, if the description mentions that a first component is formed on a second component, it may include an embodiment in which the first component and the second component are in direct contact, and it may also include an embodiment in which an additional component is formed between the first component and the second component so that the first component and the second component are not in direct contact. Furthermore, the present disclosure may repeat element numerals and/or characters in different embodiments or examples. This repetition is for the purpose of brevity and clarity and is not intended to indicate a relationship between the various embodiments and/or examples discussed.

In some embodiments of the present disclosure, terms such as “disposed”, “connected” and the like, unless otherwise defined, may refer to two components being in direct contact, or may refer to two components not being in direct contact, with an additional junction component located between the two structures. Terms related to being arranged and connected may also include situations where both structures are movable, or both structures are fixed.

In addition, the terms “first”, “second” and similar terms mentioned in this specification or the scope of the patent application are used to name different components or distinguish different embodiments or scopes, and are not used to limit the upper or lower limit of the number of components, nor are they used to limit the manufacturing order or setting order of the components.

As used herein, the terms “approximate,” “about,” and “substantially” generally mean within 10%, or within 5%, or within 3%, or within 2%, or within 1%, or within 0.5% of a given value or range. The quantities given here are approximate quantities, that is, even if there is no specific description of “about”, “approximately”, or “substantially”, the meanings of “about”, “approximately”, or “substantially” may still be implied. The term “a range between a first value and a second value” means that the range includes the first value, the second value, and other values therebetween. Furthermore, there may be a certain error between any two values or directions used for comparison. If a first value is equal to a second value, it implies that there may be an error of about 10%, or within 5%, or within 3%, or within 2%, or within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Unless otherwise defined, all terms (including technical and scientific terms) used herein have the same meanings as commonly understood by one of ordinary skill in the art. It is understood that these terms, such as those defined in commonly used dictionaries, should be interpreted as having meanings consistent with the background or context of the relevant technology and the present disclosure, and should not be interpreted in an idealized or overly formal manner unless specifically defined in the embodiments of the present disclosure.

It should be understood that, for the sake of clarity, some elements of the device are omitted in the drawings, and only some elements are schematically illustrated. In some embodiments, additional components may be added to the devices described below. In other embodiments, some of the components of the apparatus described below may be replaced or omitted. It should be understood that in some embodiments, additional operating steps may be provided before, during and/or after the device manufacturing method. In some embodiments, some of the operation steps described may be replaced or omitted, and the order of some of the operation steps described may be interchangeable.

As light-emitting elements such as micro-LEDs continue to scale down, thermal bonding processes or laser welding processes for fixing the light-emitting elements to a substrate have become increasingly complex and difficult to implement. In other words, the scaling down of light-emitting elements leads to poor yield or high cost of semiconductor structures. To this end, the present disclosure forms a packaging structure including a plurality of micro-LEDs through a mass transfer process, a coplanar process, and a redistribution process, and then transfers the packaging structures to a substrate through a transfer process to form a semiconductor structure, thereby solving at least the above-mentioned problems.

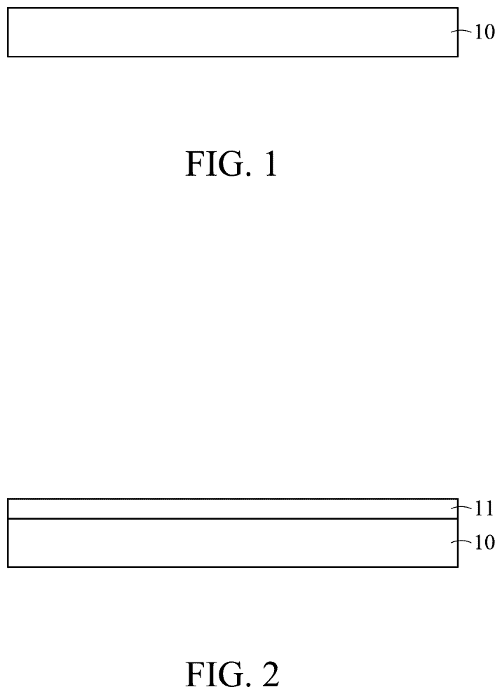

FIGS. 1 to 3, 7, 8, 10 to 12A, and 13 to 18 are schematic cross-sectional views showing the semiconductor structure at various stages in the manufacturing method according to some embodiments of the present disclosure. As shown in FIG. 1, a substrate 10 is provided. In some embodiments, the material of the substrate 10 may be or may include: Group IV elements or Group IV compounds, such as silicon (Si), diamond (C), or silicon carbide (SiC); Group III-V compounds, such as gallium nitride (GaN), aluminum gallium nitride (AlGaN), aluminum nitride (AlN), gallium phosphide (GaP), gallium arsenide (GaAs), or aluminum gallium arsenide (AlGaAs); other suitable materials; or a combination thereof, but the present disclosure is not limited thereto. In some embodiments, the substrate 10 may be or may include a flexible substrate, a soft substrate, a rigid substrate, or a combination thereof, but the present disclosure is not limited thereto. In some embodiments, the material of the substrate 10 may be or may include glass, quartz, sapphire, ceramic, other suitable materials, or a combination thereof, but the present disclosure is not limited thereto. For example, the substrate 10 may be a sapphire substrate. In some embodiments, the material of the substrate 10 may be or may include polyimide (PI), polycarbonate (PC), polyethylene terephthalate (PET), polypropylene (PP), other suitable materials, or a combination thereof, but the present disclosure is not limited thereto. In some embodiments, the substrate 10 may be or include a light-transmitting substrate, a semi-light-transmitting substrate, or an opaque substrate, but the present disclosure is not limited thereto.

As shown in FIG. 2, in some embodiments, a first release layer 11 is disposed on the substrate 10. In some embodiments, the first release layer 11 may be or may include thermal release, UV release, other suitable materials, or a combination thereof, but the present disclosure is not limited thereto. It should be noted that although FIG. 2 illustrates an embodiment in which the first release layer 11 completely covers the upper surface of the substrate 10, the present disclosure is not limited thereto. In other embodiments, the first release layer 11 may partially cover the upper surface of the substrate 10. For example, the first release layer 11 may partially cover the upper surface of the substrate 10 corresponding to the position of the micro-LED chips 12 to be disposed later.

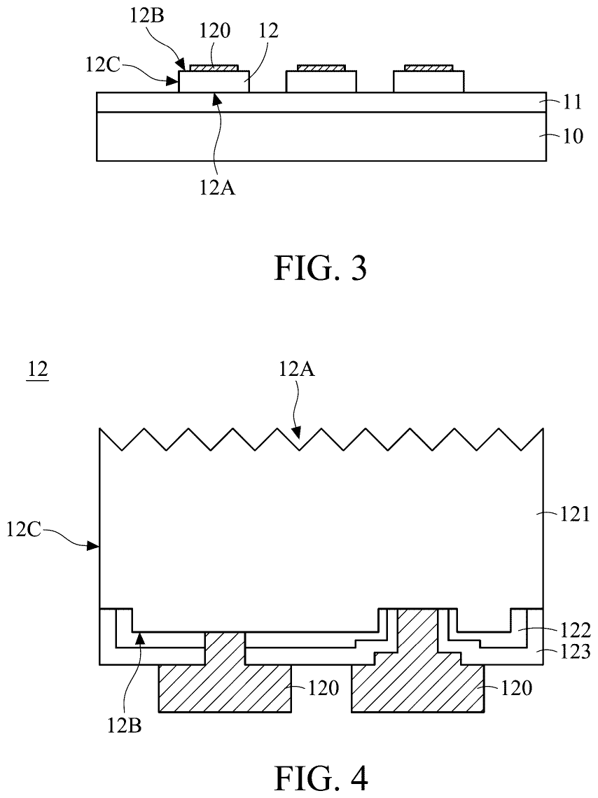

As shown in FIG. 3, in some embodiments, a plurality of micro-LED chips 12 are arranged side by side on the first release layer 11 on the substrate 10. In some embodiments, the micro-LED chips 12 may be or may include micro-LED chips 12 in flip chip type. For example, the micro-LED chips 12 may be placed on an adhesive layer of a temporary substrate (not shown), and the adhesive layer and the temporary substrate on the adhesive layer may be removed by a transfer process or a similar process, thereby transferring the micro-LED chips 12 to the first release layer 11. The transfer process may include laser transfer, stamp transfer, other suitable processes, or a combination thereof, but the present disclosure is not limited thereto. In some embodiments, the transfer process is laser transfer.

As shown in FIG. 3, in some embodiments, the micro-LED chip 12 includes a light-emitting surface 12A, an electrode surface 12B, and a plurality of sidewalls 12C. Among them, the electrode surface 12B and the light-emitting surface 12A are opposite each other, and the sidewalls 12C are located between the electrode surface 12B and the light-emitting surface 12A. It should be noted that the electrode surface 12B herein refers to the surface of the micro-LED chip 12 for disposing the electrode 120, rather than the surface of the electrode 120. In some embodiments, the electrode surface 12B of the micro-LED chip 12 is configured to be electrically connected to other electronic elements through the electrode 120, and the light-emitting surface 12A is configured to generate a light source. In the stage shown in FIG. 3, the light-emitting surface 12A of the micro-LED chip 12 faces the substrate 10, while the electrode surface 12B is away from the substrate 10.

FIG. 4 is an enlarged schematic diagram showing the micro-LED chips according to some embodiments of the present disclosure. As shown in FIG. 4, the micro-LED chip 12 includes an electrode 120 and a semiconductor stack 121, and the electrode 120 is electrically connected to the semiconductor stack 121. It should be noted that in the present disclosure, for the sake of simplicity, the micro-LED chip 12 may be shown to have one or two electrodes. For example, in order to reduce the complexity of the diagram, FIG. 3 shows one electrode 120 of the micro-LED chip 12. On the other hand, in order to illustrate the specific structure of the semiconductor stack, FIG. 4 shows two electrodes 120 of the micro-LED chip 12. In other words, the number, shape, and relative size of the electrodes 120 are merely schematic, and are depicted to indicate the physical connection relationship or electrical connection relationship between the micro-LED chip 12 and other elements. Therefore, in practical applications, the micro-LED chip 12 may have two or more electrodes 120 according to needs, and is not limited to the figures shown in the present disclosure.

In some embodiments, the micro-LED chip 12 may further include a reflective layer (e.g., the first reflective layer 122 or the second reflective layer 123 hereinafter), and the reflective layer is disposed on or around the electrode surface 12B of the micro-LED chip 12. In some embodiments, the reflective layer may include a first reflective layer 122, and the first reflective layer 122 is disposed on the semiconductor stack 121. Specifically, the first reflective layer 122 may reflect the emitted light from the semiconductor stack 121, thereby increasing the external quantum efficiency (EQE) of the micro-LED and increasing the luminous efficiency of the micro-LED.

In some embodiments where the transfer process is laser transfer, the reflective layer may further include a second reflective layer 123, and the second reflective layer 123 is disposed on the first reflective layer 122. Specifically, the second reflective layer 123 may reflect the laser beam during the laser transfer process, wherein the wavelength of the laser beam is less than 420 nm, and the first reflective layer 122 is closer to the active layer of the micro-LED chip 12 (e.g., the active layer may be a film layer in the semiconductor stack 121) than the second reflective layer 123. When the laser transfer process is performed, the second reflective layer 123 may reflect the laser beam to prevent the laser beam from damaging the micro-LED chip 12. In some embodiments, the micro-LED chip 12 only includes the first reflection layer 122 for reflecting the light emitted from the micro-LED chip (e.g., the semiconductor stack 121), but does not include the second reflection layer 123 for reflecting the laser beam from the laser during the laser transfer process.

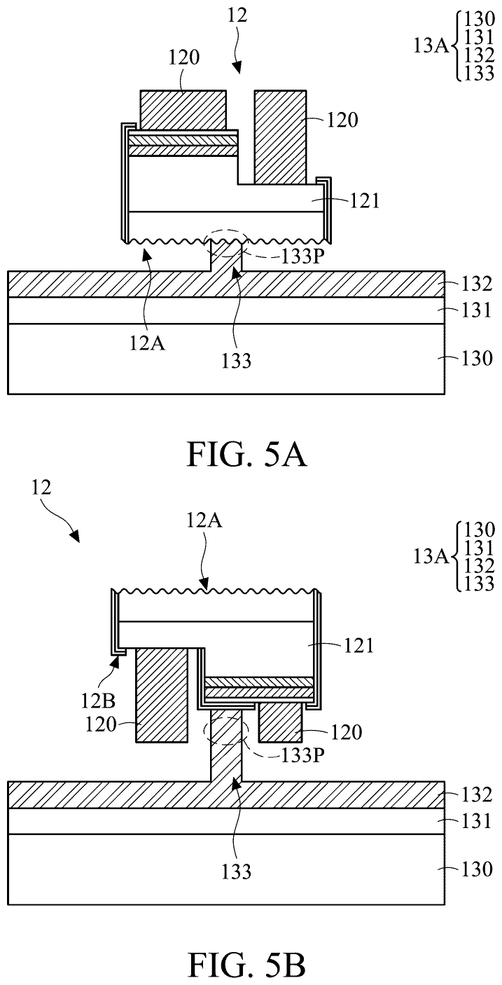

FIGS. 5A and 5B are schematic diagrams showing the micro-LED chips in the transfer process according to some embodiments of the present disclosure. In some embodiments, the micro-LED chips 12 may be transferred from a carrier 13A to the first release layer 11 by stamp transfer. Taking FIG. 5A or 5B as an example, the carrier 13A includes a carrier substrate 130, an adhesive layer 131, and a sacrificial layer 132. The adhesive layer 131 is disposed on the carrier substrate 130, and the sacrificial layer 132 is disposed on the adhesive layer 131. In some embodiments, the sacrificial layer 132 may be etched to form a first support frame 133 for supporting the micro-LED chip 12. When the micro-LED chips 12 are transferred onto the first release layer 11 by stamp transfer, each of the micro-LED chips 12 includes a first support frame breakpoint 133P obtained by breaking the first support frame 133.

As shown in FIG. 5A, in some embodiments, the first support frame breakpoint 133P (corresponding to the first support frame 133 before being broken) is located on the light-emitting surface 12A of the micro-LED chip 12. As shown in FIG. 5B, in some embodiments, the first support frame breakpoint 133P (corresponding to the first support frame 133 before being broken) is located on the electrode surface 12B of the micro-LED chip 12. However, the present disclosure is not limited thereto. The first support frame 133 may be connected to any position of the micro-LED chip 12, thereby leaving the first support frame breakpoint 133P located at various positions after being broken. For example, in some embodiments, the first support frame breakpoint 133P is located on the sidewall of the micro-LED chip 12. In some embodiments, the micro-LED chip 12 may include a plurality of first support frame breakpoints 133P.

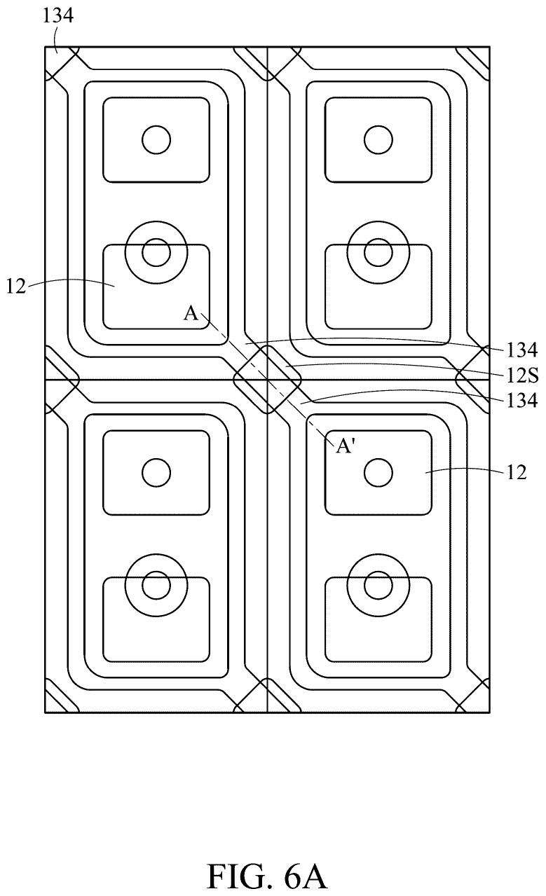

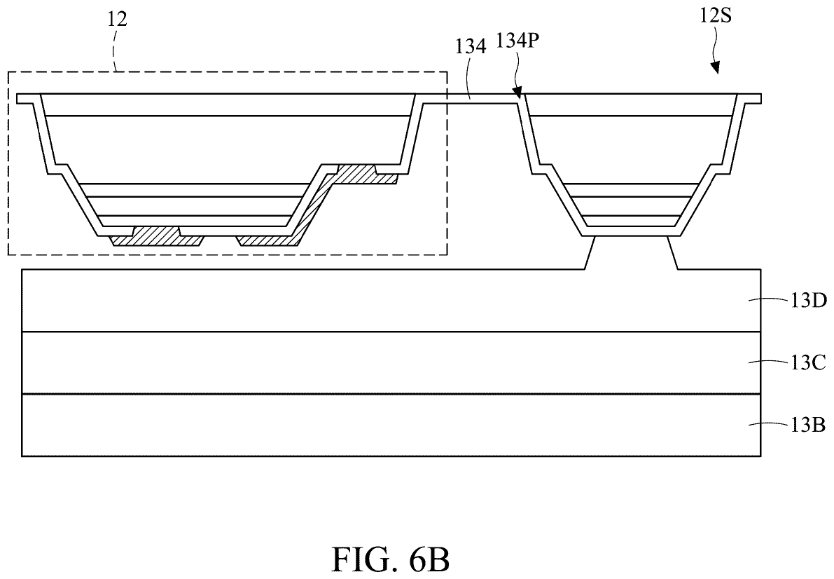

Referring to FIGS. 6A and 6B, wherein FIG. 6A is a schematically top view showing the micro-LED chips during a transfer process according to some embodiments of the present disclosure, and FIG. 6B is a schematic cross-sectional view along the line AA′ of FIG. 6A. In some embodiments, the micro-LED chips 12 may be transferred from a carrier 13B to the first release layer 11 by stamp transfer. Taking FIG. 6B as an example, the micro-LED chip 12 and the support frame structure 12S may be formed on the carrier 13B by epitaxial process, etching process, deposition process, other suitable processes, or a combination thereof. In some embodiments, the support frame structure 12S (and the micro-LED chip 12 connected thereto) may be connected to the carrier 13B through the connection layer 13C and the support frame structure layer 13D. For example, the connection layer 13C is a metal layer, an adhesive material, other suitable materials, or a combination thereof, but the present disclosure is not limited thereto. For example, the support frame structure layer 13D may include silicon dioxide (SiO₂), other suitable materials, or a combination thereof, but the present disclosure is not limited thereto.

In some embodiments, the support frame structure 12S and the micro-LED chip 12 may be formed by the same or similar process. In this case, the formed support frame structure 12S and the micro-LED chip 12 may have a mesa shape, and the support frame structure 12S and the micro-LED chip 12 may be connected to each other through the second support frame 134. When the micro-LED chips 12 are transferred onto the first release layer 11 by stamp transfer, each of the micro-LED chips 12 includes a second support frame breakpoint 134P obtained by breaking the second support frame 134.

As shown in FIG. 6A, in some embodiments, the second support frame breakpoint 134P (corresponding to the second support frame 134 before being broken) is located at a corner of the micro-LED chip 12. More specifically, the second support frame breakpoint 134P (corresponding to the second support frame 134 before being broken) is located between two adjacent micro-LED chips 12 in the diagonal direction. However, the present disclosure is not limited thereto. The second support frame 134 may be connected to any position of the micro-LED chip 12, thereby leaving second support frame breakpoints 134P located at various positions after being broken. In some embodiments, the micro-LED chip 12 may include a plurality of second support frame breakpoints 134P.

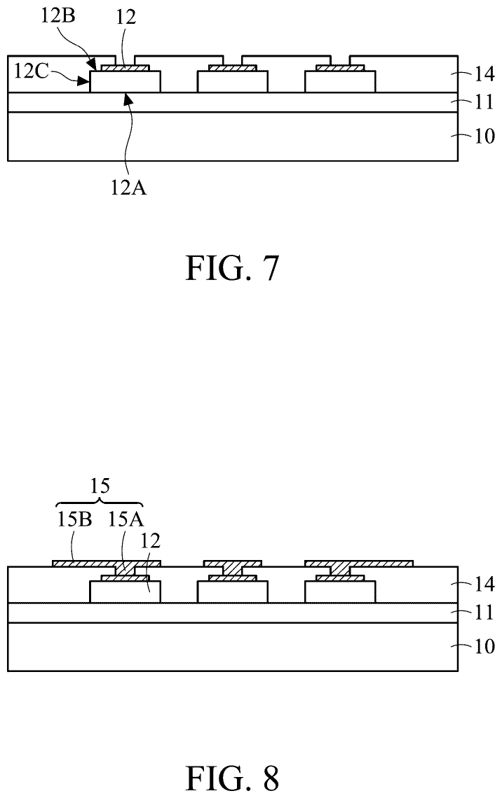

As shown in FIG. 7, a first insulating layer 14 is disposed to surround the micro-LED chips 12, and the electrode surface 12B of the micro-LED chips 12 is in direct contact with the first insulating layer 14. For example, the first insulating layer 14 may be blanketly formed on the micro-LED chips 12 by compression molding, lamination, transfer molding, other suitable methods, or a combination thereof to cover the electrode surface 12B and sidewalls 12C of the micro-LED chips 12 and the upper surface of the first release layer 11.

In some embodiments, the first insulating layer 14 may be or may include epoxy, polyimide (PI), polybenzoxazole (PBO), silicone, silicon dioxide, silicon nitride, or a combination thereof, but the present disclosure is not limited thereto. In some embodiments, the light transmittance (e.g., light transmittance in the visible light range) of the first insulating layer 14 may be less than or equal to 70%. For example, the light transmittance of the first insulating layer 14 may be 70%, 65%, 60%, 55%, 50%, 45%, 40%, 35%, or any range of values mentioned above. In some embodiments, the first insulating layer 14 may be made of or include material having a light absorption rate that is greater than 90% to adjust the light transmittance of the first insulating layer 14. For example, black dispersed particles such as carbon black may be added to the first insulating layer 14 to reduce the light transmittance of the first insulating layer 14 to less than 10%, thereby making the first insulating layer 14 appear black. By making the first insulating layer 14 appear black, the proportion of black area in the formed semiconductor structure may be increased in a top view, thereby improving the display effect of the entire device. For example, the contrast ratio of a display device including the semiconductor structure may be improved. In some embodiments, the proportion of black area in the semiconductor structure may reach more than 80%.

As shown in FIG. 8, in some embodiments, a plurality of redistribution layers 15 are disposed on the first insulating layer 14, wherein the redistribution layers 15 pass through the first insulating layer 14 and are electrically connected to the electrode 120 on the electrode surface 12B of the micro-LED chip 12. In some embodiments, the redistribution layer 15 may be formed on the electrode 120 by a process such as electroplating, sputtering, or electron gun evaporation. In this case, the contact surface between the redistribution layer 15 and the electrode 120 may have a clear boundary and may be a flat surface.

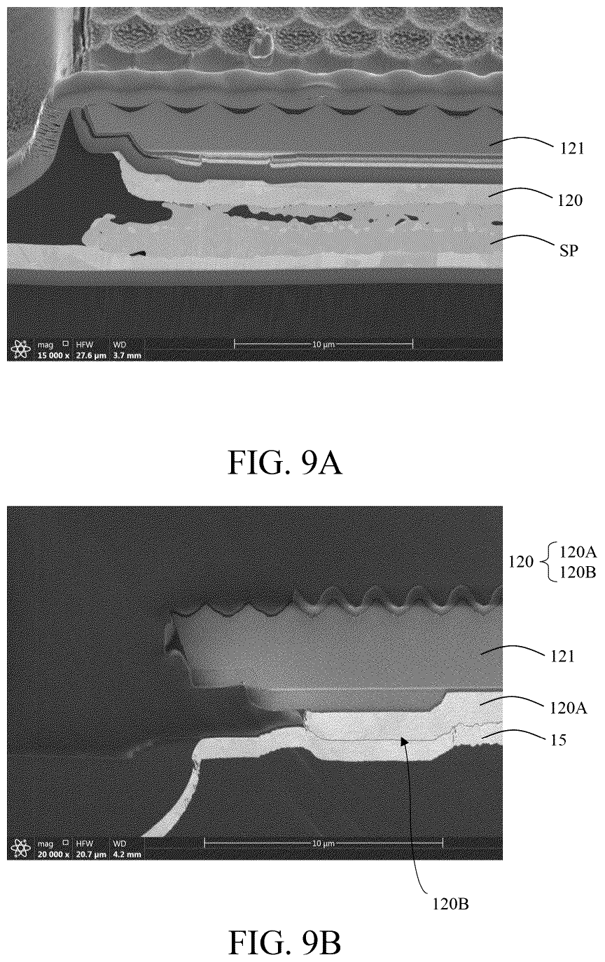

Referring to FIGS. 9A and 9B, wherein FIG. 9A is a schematic diagram showing the electrode 120 and the solder paste SP connected together by a bonding process, and FIG. 9B is a schematic diagram showing the electrode 120 and the redistribution layer 15 connected together by an electroplating process, a sputtering process, or an electron gun evaporation process. Specifically, compared to the rough interface that may be produced by the bonding process (e.g., the fuzzy interface between the electrode 120 and the solder paste SP in FIG. 9A), the contact surface between the redistribution layer 15 and the electrode 120 formed by an electroplating, a sputtering process, or an electron gun evaporation process may have a smooth interface (e.g., the clear interface between the redistribution layer 15 and the electrode 120 in FIG. 9B). In other words, the surface roughness between the redistribution layer 15 and the electrode 120 formed by an electroplating, a sputtering process, or an electron gun evaporation process is smaller than the surface roughness of the contact surface formed by the bonding process. In some embodiments, as shown in FIG. 9B, the undulations of the contact surface between the redistribution layer 15 and the electrode 120 are consistent, and the morphologies of the contact surface between the redistribution layer 15 and the electrode 120 match each other, but the present disclosure is not limited thereto. For example, the redistribution layer 15 may be conformally disposed on the electrode 120. By making the contact surface between the redistribution layer 15 and the electrode 120 have a clear boundary and a flat surface, the semiconductor structure may have higher reliability.

In some embodiments, the redistribution layers 15 are conformally formed on the surface of the electrode 120. Therefore, the redistribution layers 15 conform to the surface shape of the electrode 120. For example, as shown in FIG. 9B, the electrode 120 of the micro-LED chip 12 may have an upper portion 120A and a lower portion 120B, and a step between the upper portion 120A and the lower portion 120B. In this case, the redistribution layer 15 is disposed on the electrode 120 along the upper portion 120A, the lower portion 120B, and the step therebetween, and has a shape similar to that of the electrode 120.

As shown in FIG. 8, in some embodiments, the redistribution layer 15 may include a vertical connection part 15A and a horizontal connection part 15B, wherein the vertical connection part 15A is configured to electrically connect the micro-LED chip 12, and the horizontal connection part 15B is configured to electrically connect other electronic elements, such as the conductive piece 17 mentioned hereinafter. In some embodiments, when the total thicknesses of the semiconductor stacks 121 of the micro-LED chips 12 are different from each other, the extension lengths (or thicknesses) of the vertical connection parts 15A of the redistribution layers 15 may be different from each other. In this way, the light-emitting surfaces 12A of the plurality of micro-LED chips 12 may be substantially coplanar, and the horizontal connection parts 15B of the redistribution layers 15 corresponding to the plurality of micro-LED chips 12 may be substantially coplanar.

In some embodiments, the redistribution layers 15 may be or may include a conductive material. For example, the conductive material may include metal, metal compound, other suitable conductive materials, or a combination thereof, but the present disclosure is not limited thereto. For example, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), titanium (Ti), magnesium (Mg), zinc (Zn), germanium (Ge), or an alloy thereof. For example, the metal compound may be tantalum nitride (TaN), titanium nitride (TiN), tungsten silicide (WSi2), indium tin oxide (ITO), etc.

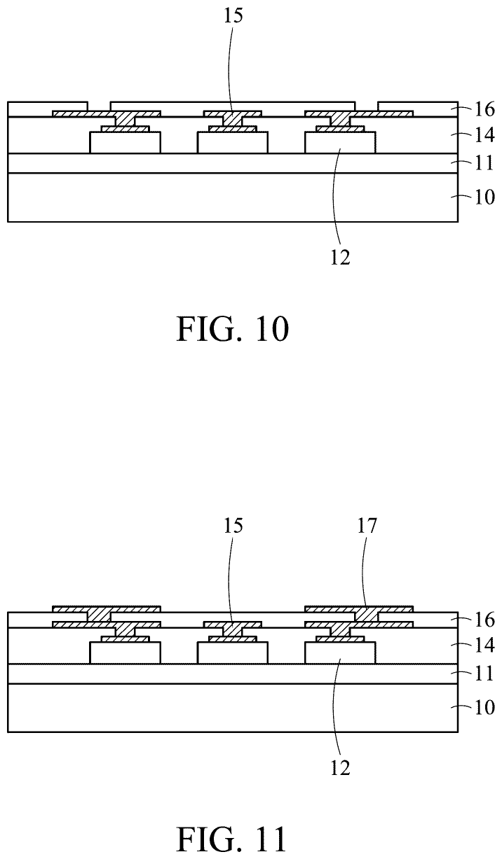

As shown in FIG. 10, in some embodiments, a second insulating layer 16 is disposed on the first insulating layer 14, wherein the second insulating layer 16 covers the redistribution layers 15. In other words, the redistribution layers 15 are buried in the second insulating layer 16. In some embodiments, the second insulating layer 16 may be or may include epoxy, polyimide, polybenzoxazole, silicone resin, silicon oxide, silicon nitride, or a combination thereof, but the present disclosure is not limited thereto. In some embodiments, the material of the second insulating layer 16 may be similar to or the same as the material of the first insulating layer 14, but the present disclosure is not limited thereto. In some embodiments, the second insulating layer 16 has an etching selectivity higher than that of the first insulating layer 14. In some embodiments, the second insulating layer 16 may include a plurality of film layers with different refractive indices, and the film layers form a distributed Bragg reflector. In other words, the reflective layer described above may not be provided, and similar or identical effects may be achieved by making the second insulating layer 16 serve as a distributed Bragg reflector.

In some embodiments, the light transmittance (e.g., light transmittance in the visible light range) of the second insulating layer 16 may be less than or equal to 70%. For example, the light transmittance of the second insulating layer 16 may be 70%, 65%, 60%, 55%, 50%, 45%, 40%, 35%, or any range of values mentioned above. In some embodiments, the second insulating layer 16 may be made of or include material having a light absorption rate that is greater than 90% to adjust the light transmittance of the second insulating layer 16. For example, black dispersed particles such as carbon black may be added to the second insulating layer 16 to reduce the light transmittance of the second insulating layer 16 to less than 10%, thereby making the second insulating layer 16 appear black. By making the second insulating layer 16 appear black, the proportion of black area in each semiconductor structure may be increased in a top view, thereby improving the display effect of the entire device.

In some embodiments, the light transmittance of the second insulating layer 16 is greater than the light transmittance of the first insulating layer 14. For example, the first insulating layer 14 may be made to be opaque black, and the second insulating layer 16 may be made to be light-transmitting or semi-light-transmitting in any color. In this case, the proportion of black area in each semiconductor structure may be maintained in a top view. In some embodiments, the proportion of black area is greater than 80%, however, the present disclosure is not limited thereto. In some embodiments, the first insulating layer 14 may be made opaque black, and the second insulating layer 16 may be made semi-light-transmitting or opaque black, so as to further increase the proportion of black area in each semiconductor structure in a top view.

As shown in FIG. 11, a plurality of conductive pieces 17 are disposed on the second insulating layer 16 and the redistribution layers 15, wherein the conductive pieces 17 are electrically connected to the redistribution layers 15. In some embodiments, the conductive pieces 17 may be pads, but the present disclosure is not limited thereto. In some embodiments, the conductive pieces 17 may be or may include a conductive material. For example, the conductive material may include metal, metal compound, other suitable conductive materials, or a combination thereof, but the present disclosure is not limited thereto. For example, the metal may be tin, copper, gold, silver, nickel, indium, platinum, palladium, iridium, titanium, chromium, tungsten, aluminum, molybdenum, titanium, magnesium, zinc, germanium, or alloys thereof. For example, the metal compound may be tantalum nitride, titanium nitride, tungsten silicide, indium tin oxide, etc. In some embodiments, the material of the conductive pieces 17 may be similar to or the same as the material of the redistribution layers 15, but the present disclosure is not limited thereto.

It should be noted that for the sake of simplicity, the figures discussed above only illustrate one group of micro-LED chips 12 (e.g., three micro-LED chips 12 shown in the figure). However, in an actual manufacturing process, the structure formed by the above process may include a plurality of groups of micro-LED chips 12, wherein each group of micro-LED chips 12 (e.g., three micro-LED chips) is covered by a continuous first insulating layer 14 and a second insulating layer 16. In some embodiments, the micro-LED chips 12 may include red, green, or blue micro-LED chips 12.

In some embodiments, the light-emitting surfaces 12A of the red, green, and blue micro-LED chips 12 have a roughened structure. In some embodiments, the light-emitting surface 12A of the green and blue micro-LED chips 12 has a uniform roughened structure. The green and blue micro-LED chips 12 have light-emitting surfaces 12A with periodically arranged concave-convex textures.

For example, the green and blue micro-LED chips 12 themselves do not have an epitaxial substrate such as a patterned sapphire substrate (PSS) (e.g., the micro-LED chip 12 includes a semiconductor stack but does not include a patterned sapphire substrate on which the semiconductor stack is grown), and its light-emitting surface 12A has periodically arranged concave-convex textures generated after debonding the patterned sapphire substrate by laser. Specifically, the mentioned concavo-convex textures may be used to enhance light extraction and adjust the directional angle of the micro-LED chip 12. In some embodiments, the light-emitting surface 12A of the red micro-LED chip 12 has a non-uniform roughened structure (e.g., non-uniform textures). In some embodiments, chemical etching may be used to produce a non-uniform roughened structure on the light-emitting surface 12A of the red micro-LED wafer 12.

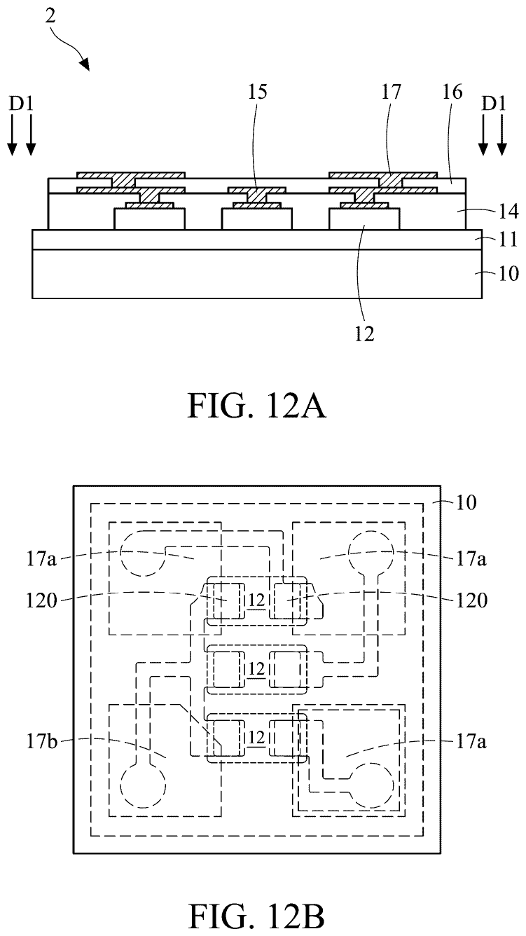

As shown in FIG. 12A, a dicing process D1 is performed on the structure formed by the above process to form a plurality of packaging structures 2 (only one packaging structures 2 is shown here). In other words, in the step shown in FIG. 12A, the first insulating layer 14 and the second insulating layer 16 covering one group of micro-LED chips 12 may be separated from the first insulating layer 14 and the second insulating layer 16 covering another group of micro-LED chips 12 by the dicing process D1, thereby forming multiple groups of packaging structures 2. Among them, each packaging structure 2 includes one group (e.g., three) of the micro-LED chips 12, the first insulating layer 14, the redistribution layer 15, the second insulating layer 16, and the conductive piece 17. It should be noted that after this step, these packaging structures 2 may still be attached to the same substrate 10. In some embodiments, the dicing process D1 may include mechanical dicing, plasma dicing, laser dicing, other suitable processes, or a combination thereof, but the present disclosure is not limited thereto.

FIG. 12B is a top view showing the packaging structure according to some embodiments of the present disclosure. As shown in FIG. 12B, the conductive piece 17 of the packaging structure 2 (corresponding to the packaging structure 1 mentioned above and the packaging structure 3 mentioned below) may be a negative conductive piece 17b or a positive conductive piece 17a. Each packaging structure 2 has three micro-LED chips 12 arranged side by side, and one electrode 120 of each micro-LED chip 12 is together electrically connected to the common negative conductive piece 17b, while the other electrode 120 of each micro-LED chip 12 is connected to the positive conductive piece 17a. In some embodiments, in a top view, the shapes of the conductive pieces 17 may be the same. In some embodiments, the shapes of the conductive pieces 17 may be different in a top view. In some embodiments, the shape of the common-pole conductive piece 17 is a square with one retracted triangular corner, and the shape of the other non-common-pole conductive pieces 17 are squares. In some embodiments, the retracted triangular corner of the common-pole conductive piece 17 may be located at the upper left corner, upper right corner, lower left corner, or lower right corner of the square. In some embodiments, the shape of the common-pole conductive pieces 17 is a square with two retracted triangular corners. It should be noted that the structure shown in FIG. 12B is only an example and the present disclosure is not limited thereto. In other embodiments, the packaging structure 2 may have more than three or less than three micro-LED chips 12, and the micro-LED chips 12 may be connected to different conductive pieces 17. In some embodiments, the electrode connection methods of the micro-LED chip 12 in the packaging structure 2 may be different from the above. For example, one electrode 120 of each micro-LED chip 12 is electrically connected to a common positive conductive piece, and the other electrode 120 of each micro-LED chip 12 is connected to a negative conductive piece (not shown).

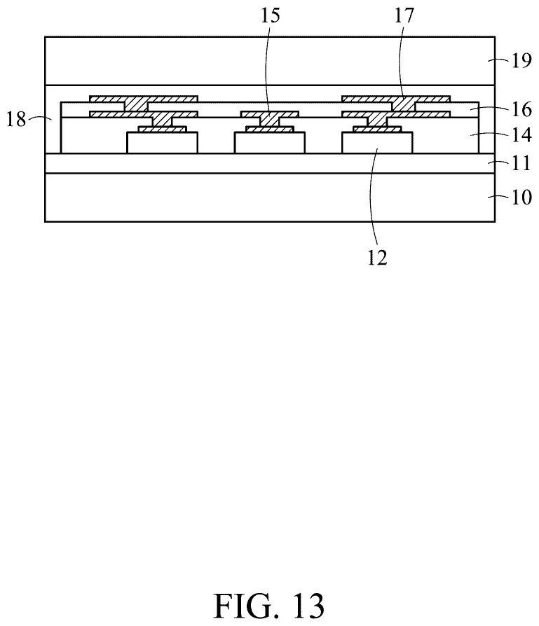

As shown in FIG. 13, the adhesive material 18 is disposed on the second insulating layer 16 and the conductive piece 17. In some embodiments, the adhesive material 18 may be or may include epoxy, polyimide (PI), polybenzoxazole (PBO), benzocyclobutene (BCB), or a combination thereof, but the present disclosure is not limited thereto. It should be noted that although FIG. 13 illustrates an embodiment in which the adhesive material 18 completely covers the packaging structure 2, the present disclosure is not limited thereto. In other embodiments, the adhesive material 18 may cover the upper surfaces of the second insulating layer 16 and the conductive piece 17, but not cover the side surfaces of the second insulating layer 16 and the first insulating layer 14. In some embodiments, the adhesive material 18 may be UV release glue that reacts with the laser beam used hereinafter. In some embodiments, the adhesive material 18 is decomposed after absorbing the laser beam, so that the packaging structure 2 including the micro-LED chip 12 is lifted off from the adhesive material 18. In some embodiments, the wavelength of the laser beam used is less than 420 nm. For example, the wavelength is 248, 260, 280, 355 nm, etc., but the present disclosure is not limited thereto.

As shown in FIG. 13, a substrate 19 is provided on the adhesive material 18. In some embodiments, the substrate 19 may be or may include: Group IV elements or Group IV compounds; Group III-V compounds; other suitable materials; or a combination thereof, but the present disclosure is not limited thereto. In some embodiments, the substrate 19 may be or may include a flexible substrate, a soft substrate, a rigid substrate, or a combination thereof, but the present disclosure is not limited thereto. In some embodiments, the substrate 19 may be or may include glass, quartz, sapphire, ceramic, silicon substrate, plastic substrate, other suitable materials, or a combination thereof, but the present disclosure is not limited thereto. In some embodiments, the substrate 19 may be or may include polyimide (PI), polycarbonate (PC), polyethylene terephthalate (PET), polypropylene (PP), other suitable materials, or a combination thereof, but the present disclosure is not limited thereto. In some embodiments, the substrate 19 may be or include a light-transmitting substrate, a semi-light-transmitting substrate, or an opaque substrate, but the present disclosure is not limited thereto. In some embodiments, the material of the substrate 19 is the same as or similar to that of the substrate 10, but the present disclosure is not limited thereto.

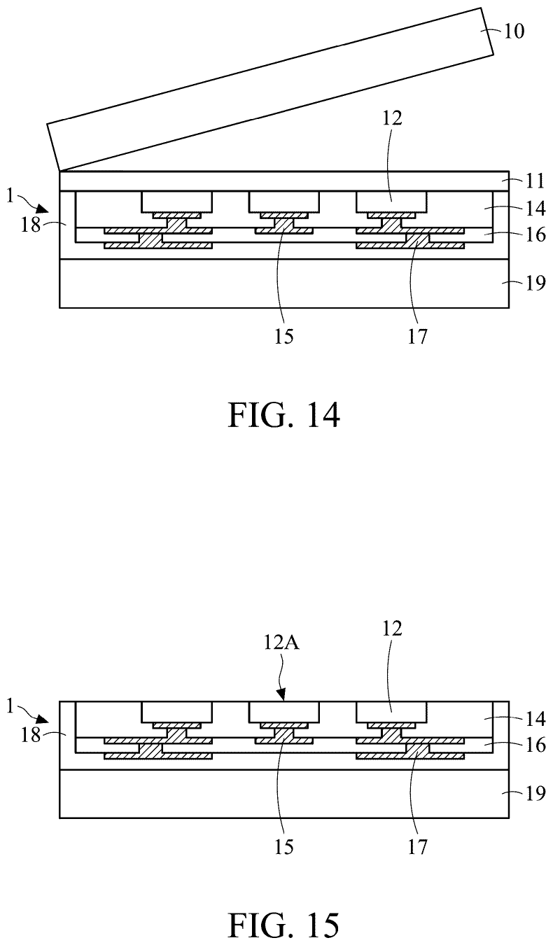

As shown in FIGS. 14 and 15, the packaging structure 1 formed by the above steps is flipped over, and the substrate 10 and the first release layer 11 are removed. In some embodiments, the substrate 10 may be removed by a laser lift-off process, an etching process, a grinding process, other suitable processes, or a combination thereof, but the present disclosure is not limited thereto. For example, the first release layer 11 between the substrate 10 and the micro-LED chip 12 may be removed by applying light or heat to remove the substrate 10. After the substrate 10 and the first release layer 11 are removed, the light-emitting surface 12A of the micro-LED chip 12 is exposed. In some embodiments, in order to avoid the first release layer 11 from remaining on the light-emitting surface 12A, a longer removal process may be performed so that the first insulating layer 14 is recessed relative to the light-emitting surface 12A of the micro-LED chip 12. As a result, the first insulating layer 14 and the light-emitting surface 12A of the micro-LED chip 12 may not be coplanar, but the present disclosure is not limited thereto.

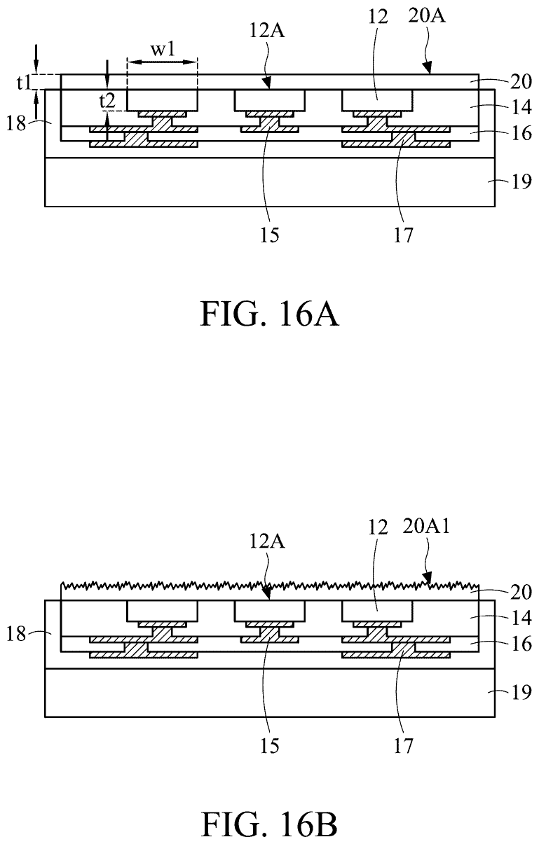

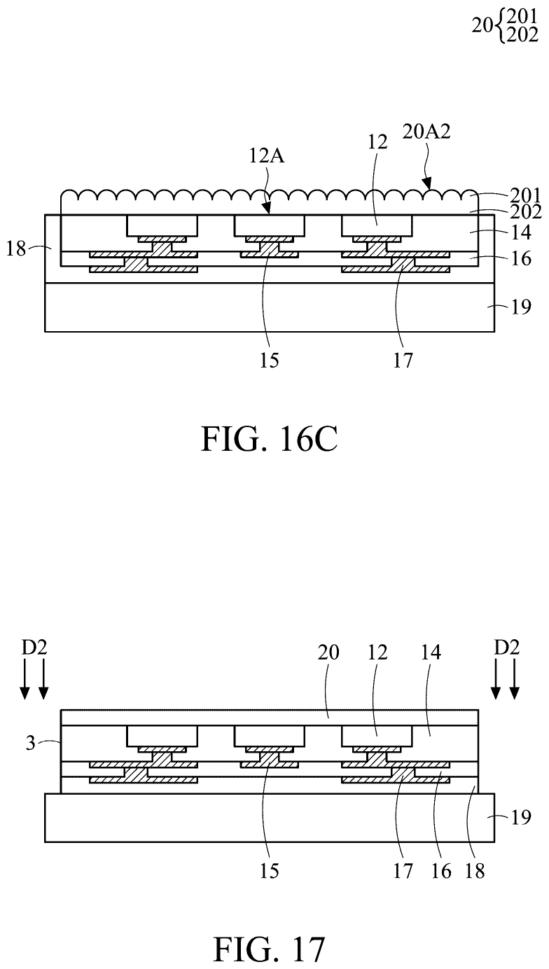

As shown in FIG. 16A, a light-transmitting layer 20 is disposed on the micro-LED chips 12 and the first insulating layer 14. For example, the light-transmitting layer 20 may be blanket formed on the micro-LED chips 12 arranged side by side by compression molding, lamination, transfer molding, other suitable methods, or a combination thereof to cover the light-emitting surfaces 12A of the micro-LED chips 12. In other words, the light-emitting surface 12A of the micro-LED chip 12 faces the light-transmitting layer 20. In some embodiments, the light-transmitting layer 20 may be or may include epoxy, silicone, polyurethane, other suitable materials, or a combination thereof, but the present disclosure is not limited thereto. In some embodiments, the light-transmitting layer 20 has an etching selectivity higher than that of the first insulating layer 14 or the second insulating layer 16.

In some embodiments, the light emitted by the micro-LED chips 12 is transmitted outwards from the light-emitting surfaces 12A and the light-transmitting layer 20 in sequence. Therefore, the light transmittance of the light-transmitting layer 20 (e.g., the light transmittance in the visible light range) may be greater than or equal to 80% to provide a better display effect, but the present disclosure is not limited thereto. For example, the light transmittance of the light-transmitting layer 20 may be 80%, 85%, 90%, 95%, 100%, or any range of values mentioned above. In some embodiments, the light transmittance of the light-transmitting layer 20 is greater than the light transmittance of the first insulating layer 14 or the second insulating layer 16.

In some embodiments, the light-transmitting layer 20 has a first thickness t1, and the micro-LED chips 12 have a second thickness t2, wherein the ratio of first thickness t1 to second thickness t2 is between 1:100 and 10:1, but the present disclosure is not limited thereto. For example, the ratio of the thickness t1 of the light-transmitting layer 20 to the second thickness t2 of the micro-LED chip 12 may be 1:100, 1:50, 1:2, 1:1, 2:1, 3:1, 5:1, 10:1, or any value or range of values mentioned above. By making the thickness of the light-transmitting layer 20 and the thickness of the micro-LED chip 12 present a specific relationship, the display effect of the entire device may be effectively improved.

In some embodiments, the surface 20A of the light-transmitting layer 20 away from the micro-LED chip 12 may have a roughened structure to enhance display effects. For example, the light from the micro-LED chips 12 may be converged or diverged by using an uneven surface or a surface with a specific curvature. FIGS. 16B and 16C are schematic diagrams showing the light-transmitting layer with the roughened structure of the semiconductor structure according to some embodiments of the present disclosure. As shown in FIG. 16B, the light-transmitting layer 20 may have an irregular roughened surface 20A1. In this case, the light emitted from the micro-LED chips 12 is scattered by the roughened surface 20A1, so that the light may be evenly emitted. As shown in FIG. 16C, the light-transmitting layer 20 may also have a regular roughened surface 20A2. For example, the light-transmitting layer 20 may include a body 202 and a plurality of lens units 201. The lens units 201 protrude in an array from the surface of the body 202 away from the micro-LED chip 12. However, the present disclosure is not limited thereto. In other embodiments, the number of the lens units 201 of the light-transmitting layer 20 may correspond to the number of the micro-LED chips 12. For example, when the number of the micro-LED chips 12 is three, the number of the lens units 201 may also be three. In this case, each of the lens units corresponds to one micro-LED chip 12 and is disposed on the micro-LED chip 12 to achieve the effect of controlling light.

As shown in FIG. 17, a dicing process D2 is performed on the structure formed by the above process to form a plurality of packaging structures 3 (only one packaging structures 3 is shown here). In other words, in the step shown in FIG. 15, the adhesive material 18 covering one set of micro-LED chips 12 and the adhesive material 18 covering another set of micro-LED chips 12 may be separated from each other by the dicing process D2, thereby forming the packaging structures 3. Each packaging structure 3 includes one group of the micro-LED chips 12 (e.g., three micro-LED chips), the first insulating layer 14, the redistribution layer 15, the second insulating layer 16, the conductive piece 17, and the adhesive material 18. It should be noted that after this step, these packaging structures 3 may still be attached to the same substrate 19. In some embodiments, the dicing process D2 may include mechanical dicing, plasma dicing, laser dicing, other suitable processes, or a combination thereof, but the present disclosure is not limited thereto.

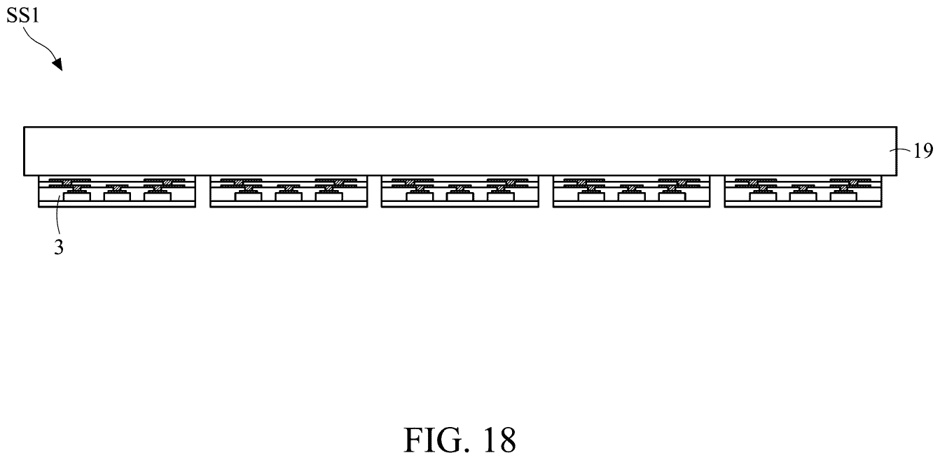

As shown in FIG. 18, the packaging structures 3 and the substrate 19 are flipped over to obtain the semiconductor structure SS1. Specifically, the semiconductor structure SS1 includes the packaging structures 3 and the substrate 19, wherein the packaging structures 3 are arranged side by side. In the semiconductor structure SS1 of the present embodiment, the substrate 19 is disposed on the packaging structure 3, and the conductive pieces 17 is located between the substrate 19 and the micro-LED chips 12.

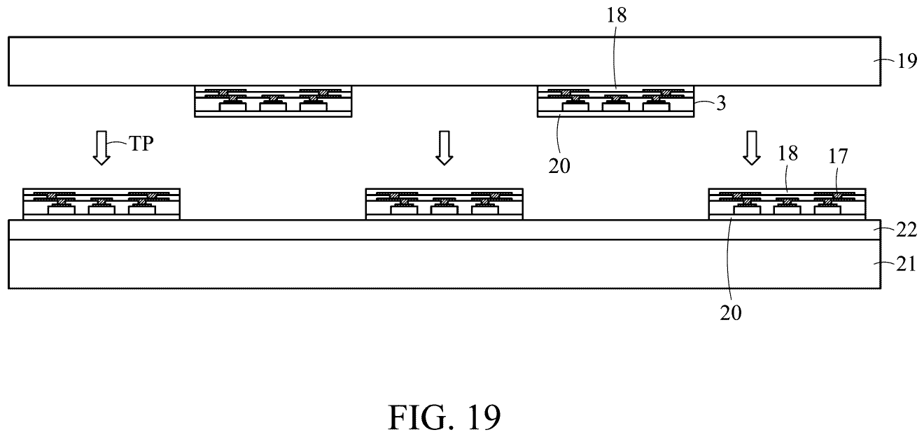

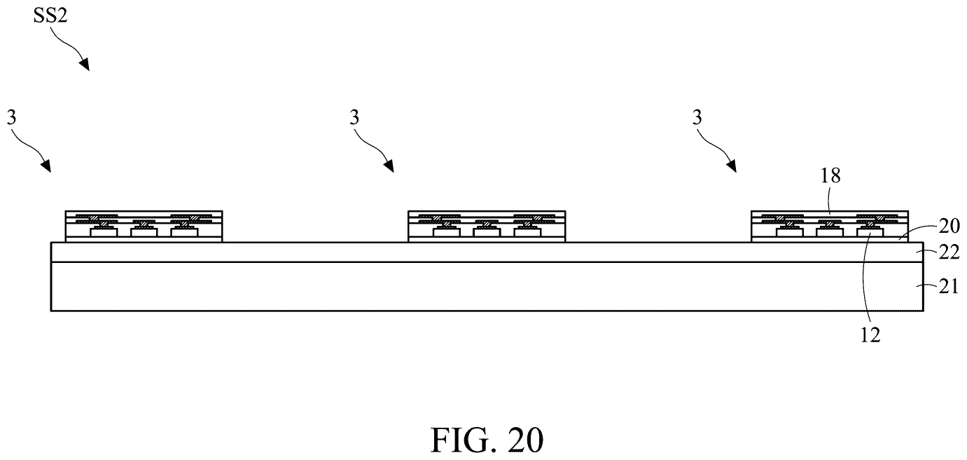

FIGS. 19 and 20 are schematic cross-sectional views showing the semiconductor structure at various stages in the manufacturing method according to other embodiments of the present disclosure. It should be noted that the semiconductor structure SS1 and the manufacturing method thereof shown in FIG. 19 may refer to FIG. 1 to FIG. 18, but the present disclosure is not limited thereto. As shown in FIG. 19, in order to facilitate subsequent processing, the packaging structures 3 may be transferred from the substrate 19 to the substrate 21 through a transfer process TP, so that the conductive piece 17 and the adhesive material 18 thereon face away from the substrate 21 and the light-transmitting layer 20 faces the substrate 21. For example, the transfer process may include laser transfer, other suitable processes, or a combination thereof, but the present disclosure is not limited thereto. In some embodiments, the transfer process is laser transfer.

As shown in FIG. 20, after performing the transfer process TP, the semiconductor structure SS2 is obtained. Specifically, the semiconductor structure SS2 includes the packaging structures 3 and the substrate 21, wherein the packaging structures 3 are arranged side by side. In the semiconductor structure SS2 of the present embodiment, the substrate 21 is disposed on the packaging structures 3, and the light-transmitting layer 20 is disposed on the substrate 21 and located between the substrate 21 and the micro-LED chips 12. In some embodiments, the pitch of the packaging structures 3 of the semiconductor structure SS2 is equal to the pitch of the packaging structures 3 of the semiconductor structure SS1. In some embodiments, the pitch of the packaging structures 3 of the semiconductor structure SS2 is greater than the pitch of the packaging structures 3 of the semiconductor structure SS1. That is, the packaging structures 3 may be kept equidistant after the transfer, or the packaging structures 3 may be moved away from each other after the transfer.

In some embodiments, the semiconductor structure SS2 may further include a second release layer 22, and the second release layer 22 is disposed between the substrate 21 and the packaging structures 3. In some embodiments, the second release layer 22 may be or may include a pyrolytic adhesive, a photolytic adhesive, other suitable materials, or a combination thereof, but the present disclosure is not limited thereto. It should be noted that although FIG. 18 illustrates an embodiment in which the second release layer 22 completely covers the upper surface of the substrate 21, the present disclosure is not limited thereto. In other embodiments, the second release layer 22 may partially cover the upper surface of the substrate 21. For example, the second release layer 22 may partially cover the upper surface of the substrate 21 corresponding to the position of the packaging structures 3.

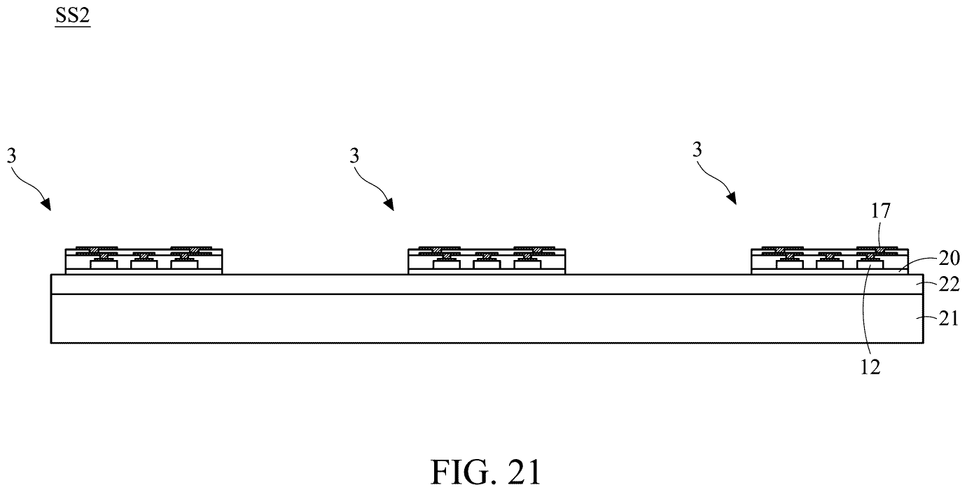

FIGS. 21 to 23 are schematic cross-sectional views showing the display device at various stages in the manufacturing method of according to other embodiments of the present disclosure. It should be noted that in these embodiments, the semiconductor structure SS2 as shown in FIG. 20 may be used and attached to a display backplane to form a display device. Continuing from FIG. 20, as shown in FIG. 21, the adhesive material 18 may be removed to expose the conductive piece 17. For example, inductively coupled plasma (ICP) etching may be used to remove the adhesive material 18, but the present disclosure is not limited thereto.

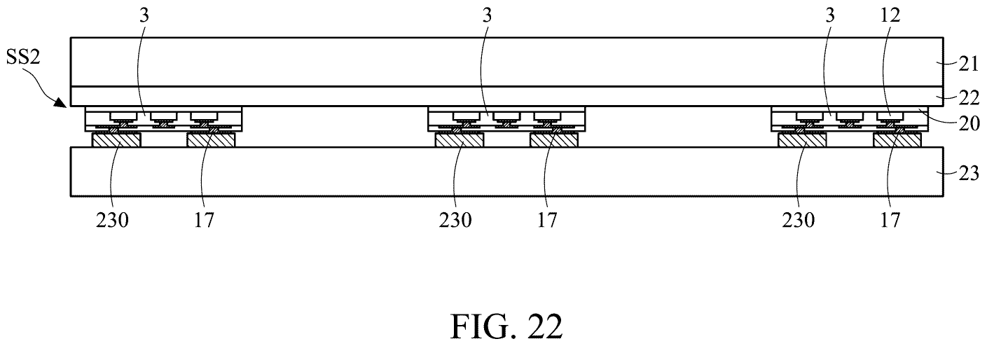

As shown in FIG. 22, a display backplane 23 is provided, and a plurality of conductive components 230 are provided on the display backplane 23. The conductive pieces 17 of the packaging structures 3 of the semiconductor structure SS2 correspond to the conductive components 230 of the display backplane 23. Next, the packaging structures 3 are electrically connected to the display backplane 23. For example, the conductive pieces 17 of the packaging structures 3 may be connected to the conductive components 230 of the display backplane 23 by bonding, welding, other suitable methods, or a combination thereof, but the present disclosure is not limited thereto.

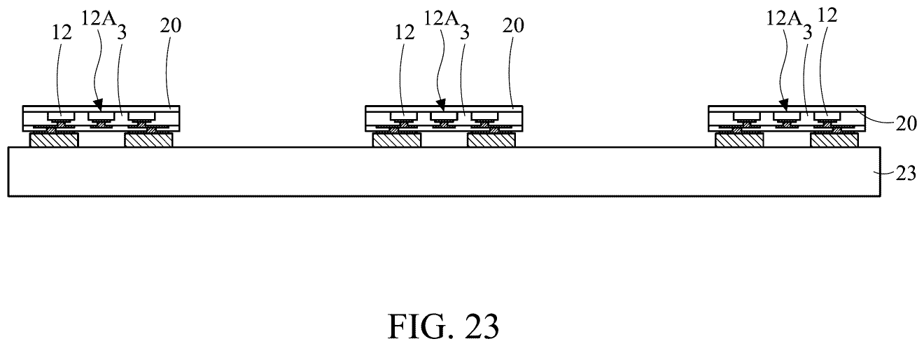

As shown in FIG. 23, the substrate 21 is removed. In some embodiments, the substrate 21 may be removed by a laser lift-off process, an etching process, a grinding process, other suitable processes, or a combination thereof, but the present disclosure is not limited thereto. For example, the second release layer 22 between the substrate 21 and the micro-LED chips 12 may be removed by applying light or heat to remove the substrate 21. After the substrate 21 and the second release layer 22 are removed, the light-transmitting layer 20 is exposed. In this case, the light-emitting surfaces 12A of the micro-LED chips 12 may face the side away from the display backplane 23.

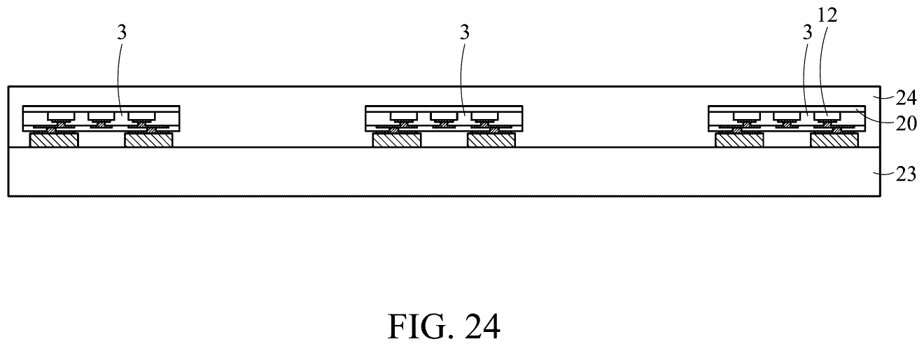

As shown in FIG. 24, a packaging material 24 is disposed on the packaging structures 3 to form a display device. In some embodiments, the packaging material 24 may be or may include epoxy, silicone, polyurethane, other suitable materials, or a combination thereof, but the present disclosure is not limited thereto. In some embodiments, the light emitted by the micro-LED chips 12 in the packaging structures 3 is transmitted outwards in sequence from the light-emitting surfaces 12A, the light-transmitting layer 20, and the packaging material 24. Therefore, the light transmittance (e.g., light transmittance in the visible light range) of the packaging material 24 may be greater than or equal to 80% to provide a better display effect, but the present disclosure is not limited thereto. For example, the light transmittance of the packaging material 24 may be 80%, 85%, 90%, 95%, 100% or any range of values mentioned above.

In summary, the present disclosure forms a packaging structure including a plurality of micro-LEDs through a mass transfer process, a coplanar process, and a redistribution process, and then transfers the packaging structures to a substrate through a transfer process to form a semiconductor structure. In this way, the formed semiconductor structure includes a plurality of packaging structures and a substrate, which is beneficial to subsequent processing applications, thereby effectively solving the problem of poor yield and high cost of the semiconductor structure in the prior art.

In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a plurality of packaging structures arranged side by side, wherein each of the plurality of packaging structures comprises:
a light-transmitting layer;
a plurality of micro light-emitting diode (micro-LED) chips arranged side by side on the light-transmitting layer, wherein each of the plurality of micro-LED chips comprises an electrode surface and a light-emitting surface opposite to the electrode surface, wherein the light-emitting surfaces of the plurality of micro-LED chips face the light-transmitting layer;
a first insulating layer disposed on the light-transmitting layer and surrounding the plurality of micro-LED chips;
a plurality of redistribution layers disposed on the first insulating layer and passing through the first insulating layer to be electrically connected to the electrode surfaces of the plurality of micro-LED chips;
a second insulating layer disposed on the first insulating layer; and
a plurality of conductive pieces disposed on the second insulating layer and passing through the second insulating layer to be electrically connected to the plurality of redistribution layers; and
a substrate disposed on the plurality of packaging structures, wherein the plurality of conductive pieces are between the substrate and the plurality of micro-LED chips.

2. The semiconductor structure as claimed in claim 1, wherein each of the plurality of micro-LED chips comprises a support frame breakpoint, and the support frame breakpoint is located on the light-emitting surface, the electrode surface, or a sidewall of each of the plurality of micro-LED chips.

3. The semiconductor structure as claimed in claim 1, wherein each of the plurality of micro-LED chips comprises a support frame breakpoint, and the support frame breakpoint is located at a corner of each of the plurality of micro-LED chips.

4. The semiconductor structure as claimed in claim 1, wherein the light-transmitting layer has a first thickness, and the plurality of micro-LED chips have a second thickness, wherein a ratio of first thickness to second thickness is between 1:100 and 10:1.

5. The semiconductor structure as claimed in claim 1, wherein a surface of the light-transmitting layer away from the plurality of micro-LED chips has a roughened structure.

6. The semiconductor structure as claimed in claim 1, wherein the light-transmitting layer comprises a body and a plurality of lens units, and the plurality of lens units protrude in an array from a surface of the body away from the plurality of micro-LED chips.

7. The semiconductor structure as claimed in claim 1, wherein the light-transmitting layer has an etching selectivity higher than that of the second insulating layer.

8. The semiconductor structure as claimed in claim 1, wherein a light transmittance of the light-transmitting layer is greater than a light transmittance of the first insulating layer.

9. The semiconductor structure as claimed in claim 1, wherein the light-transmitting layer comprises epoxy, silicone, polyurethane, or a combination thereof.

10. The semiconductor structure as claimed in claim 1, wherein the first insulating layer is non-coplanar with the light-emitting surfaces of the plurality of micro-LED chips.

11. A semiconductor structure comprising:
a substrate; and
a plurality of packaging structures arranged side by side on the substrate, wherein each of the plurality of packaging structures comprises:
a light-transmitting layer;
a plurality of micro light-emitting diode (micro-LED) chips arranged side by side on the light-transmitting layer, wherein each of the plurality of micro-LED chips comprises an electrode surface and a light-emitting surface, and the electrode surface and the light-emitting surface are opposite each other, wherein the light-emitting surfaces of the plurality of micro-LED chips face the light-transmitting layer;
a first insulating layer disposed on the light-transmitting layer and surrounding the plurality of micro-LED chips;
a plurality of redistribution layers disposed on the first insulating layer and passing through the first insulating layer to be electrically connected to the electrode surfaces of the plurality of micro-LED chips;
a second insulating layer disposed on the first insulating layer; and
a plurality of conductive pieces disposed on the second insulating layer and passing through the second insulating layer to be electrically connected to the plurality of redistribution layers.

12. The semiconductor structure as claimed in claim 11, further comprising a release layer, and the release layer disposed between the substrate and the packaging structure.

13. The semiconductor structure as claimed in claim 11, wherein the plurality of micro-LED chips further comprise a reflective layer disposed on or around the electrode surface.

14. The semiconductor structure as claimed in claim 11, wherein one of the plurality of micro-LED chips comprises an electrode on the electrode surface, and the redistribution layer is conformally formed on a surface of the electrode.

15. The semiconductor structure as claimed in claim 14, wherein the electrode of the one micro-LED chip comprises an upper portion and a lower portion, and a step between the upper portion and the lower portion, wherein the redistribution layer is disposed on the electrode along the upper portion, the lower portion, and the step therebetween, and is conformally formed on a surface of the electrode.

16. The semiconductor structure as claimed in claim 11, wherein the second insulating layer comprises a plurality of film layers with different refractive indices to form a distributed Bragg reflector.

17. The semiconductor structure as claimed in claim 11, wherein the second insulating layer comprises a material having a light absorption rate greater than 90%.

18. The semiconductor structure as claimed in claim 11, wherein one of the plurality of micro-LED chips comprises a support frame breakpoint, and the support frame breakpoint is located on the light-emitting surface, the electrode surface, or a sidewall of each of the plurality of micro-LED chips.

19. The semiconductor structure as claimed in claim 11, wherein a material of the plurality of conductive pieces comprises tin, copper, gold, silver, nickel, indium, platinum, palladium, iridium, titanium, chromium, tungsten, aluminum, molybdenum, titanium, magnesium, zinc, germanium, or alloys thereof.

20. The semiconductor structure as claimed in claim 11, wherein each of the plurality of micro-LED chips comprises a support frame breakpoint, and the support frame breakpoint is located at a corner of each of the plurality of micro-LED chips.
